(19) United States
(12) Patent Application Publication
(10) Pub. No.: US 2006/0264050 A1
(43) Pub. Date: Nov. 23, 2006

(54) Method and apparatus for chemical mixing in a single wafer process

(76) Inventors: Steven Verhaverbeke, San Francisco, CA (US); J. Kelly Truman, Morgan Hill, CA (US); Rick R. Endo, San Carlos, CA (US); Alexander Ko, Sunnyvale, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/496,887

(22) Filed: Jul. 31, 2006

Related U.S. Application Data
(63) Continuation of application No. 09/891,833, filed on Jun. 25, 2001.
(60) Provisional application No. 60/214,056, filed on Jun. 26, 2000.

(51) Int. Cl. C23G 1/00; B08B 3/00; H01L 21/302

(52) U.S. Cl. 438/689; 134/2; 134/34

(57) ABSTRACT

A method of and apparatus for mixing chemicals in a single wafer process. According to the present invention a chemical is fed into a valve system having a tube of a known volume. The chemical is fed into the valve system to fill the tube with a chemical to generate a measured amount of the chemical. The measured amount of chemical is then used in a single wafer process.

This application is a continuation of U.S. patent application Ser. No. 09/891,833, currently pending, filed Jun. 25, 2001, which claims the benefit of U.S. Provisional application Ser. No. 60/214,056, filed Jun. 26, 2000, entitled METHOD AND APPARATUS FOR CHEMICAL MIXING IN A SINGLE WAFER PROCESS.

### BACKGROUND OF THE INVENTION

1. Field of the Invention

The present invention relates to the field of semiconductor manufacturing and more specifically to a method and apparatus for mixing a precise amount of chemicals in a single wafer process.

2. Discussion of Related Art

Wet etching and wet cleaning of silicon wafers is typically done by immersing the wafers into a liquid. This can also be done by spraying a liquid onto a wafer or a batch of wafers. Wet wafer cleaning and etching is traditionally done in a batch mode. Because of the need for a shorter cycle time in chip manufacturing, there is a need for fast single wafer processing. When using single wafer processing, the amount of chemicals in processes is much smaller than when using batch processing. Even though the quantities in use at any time are much smaller than in batch processing, the accuracy of mixing has to be similar to batch processing.

When performing wet etching operations, the accuracy of the etch has to be smaller than 1% 1 sigma total variation on a 300 mm wafer. This variation is the result of variations in contact time over the wafer when spraying chemicals, the variation in temperature in the etching chemical and on the wafer surface and the variation in chemical concentration. Therefore the variation in chemical concentration has to be controlled very tight. When using wet chemicals for cleaning instead of etching wafers, the accuracy of mixing can be relaxed. Traditionally, in batch equipment, the chemicals are premixed in an off-line tank, where water and chemicals are added separately. Usually, at first chemicals are added and the amount is monitored by monitoring the level. Then the water is added to the full level. The chemicals in this off-line tank can be heated and when needed are transferred to the etching or cleaning tank. Inside the tank the concentration can be monitored and additional chemical or water can be added to adjust for any variations. Alternatively, such as in a flow-through reactor (e.g. CFM Technologies), chemicals are measured in a tube in which the level is monitored and are injected in a stream of DI water of which the flow is controlled. These techniques work well for mixing chemical volumes of the order of 1 to 41 of chemicals with multiple volumes of DI water.

Most single wafer wet processors available today use a similar principle. I.e., chemicals are premixed in an off-line tank and then are pumped to the single wafer chamber when needed. The problem with this approach is that for every mixing ratio of chemical, a specific mixing tank has to be constructed and chemicals have to be mixed in quantities far exceeding the necessary amount for the processing of one wafer.

Thus, there is a need for a simple and accurate mixing system coupled to a single wafer wet processing chamber that can be connected to the bulk supply of the semiconductor fab directly, without the use of a big pre-mixing tank for multiple wafer processing

### SUMMARY OF THE INVENTION

A method of and apparatus for mixing chemicals in a single wafer process. According to the present invention a chemical is fed into a valve system having a tube of a known volume. The chemical is fed into the valve system to fill the tube with a chemical to generate a measured amount of the chemical. The measured amount of chemical is then used in a single wafer process.

### BRIEF DESCRIPTION OF THE DRAWINGS

FIG. 1 is an illustration of a mixing apparatus in which a 6-port valve is being charged.

FIG. 2 is an illustration of a mixing apparatus which is ready for use.

FIG. 3 is an illustration of a mixing apparatus which utilizes two 6-port valves.

FIG. 4 is an illustration of a mixing apparatus wherein chemical is pushed through a 6-port valve and mixed immediately with a stream of water to combine into a chemical mixture which is sprayed onto a spinning wafer.

FIG. 5 is an illustration of a gas mixing apparatus wherein a 6-port valve is filled with a chemical and N₂ is separated from the chemical using a hydrophobic membrane and a drain valve.

FIG. 6 is an illustration on how two 3-port valves can provide the functionality of a single 6-port valve.

### DETAILED DESCRIPTION OF THE PRESENT INVENTION

The present invention is a method and apparatus for chemical mixing in a single wafer process. In the following description a number of specific details are set forth in order to provide a thorough understanding of the present invention. One of ordinary skill in the art will understand that these specific details are for illustrative purposes only and are not intended to limit the scope of the present invention. Additionally, in other instances, well-known processing techniques and equipment have not been set forth in particular detail in order to not unnecessarily obscure the present invention.

The present invention describes a method and apparatus for mixing a precise amount of chemicals in a single wafer process. The present invention utilizes a 6-port valve to accurately measure precise amounts of a chemical in a chemical mix or supply system. Because small amounts of chemicals can be precisely measured with a 6-port valve, the present invention provides a simple and accurate mixing system for single wafer processing where very small amounts of chemicals are used. The 6-port valve mixing apparatus of the present invention can be used to mix chemicals during or before use in a single wafer process.

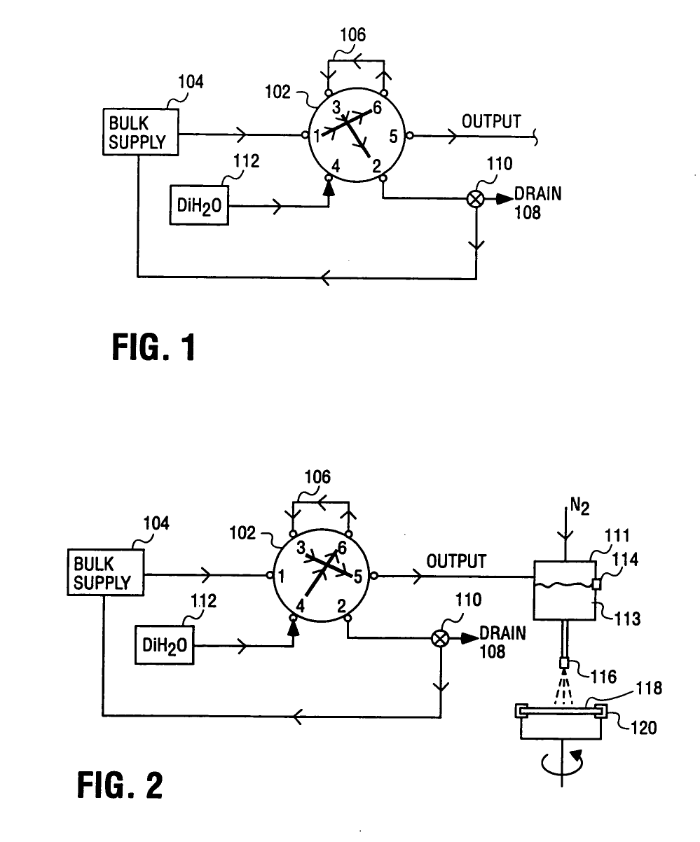

FIG. 1 is an illustration of a chemical mixing system which utilizes a 6-port valve 102. A 6-port valve is a valve system which has six individual ports (1-6) and which contains two internal tube connections coupling two sets of ports. In FIG. 1, ports 3 and 2 are connected together by an internal connection as are ports 1 and 6. The position of 6-port valve 102 in FIG. 1 is known as the “charging” position and is the position in which a known amount of chemical from a bulk supply 104 can be measured. Bulk supply 104 is coupled to port 1 of valve 102 and chemicals flow into port 1 and through an internal tube connection to port 6. The chemicals flow into an external measuring tube 106 externally connected between ports 3 and 6, and then flows out into port 3 and through an internal connection in valve 102 to port 2 and then out to a drain or valved 110 back into bulk supply 104.

In the present invention measuring tube 106 has a precisely known volume, so that when it is filled or “charged” measuring tube 106 contains a precise amount of chemicals. The amount of chemicals can be varied by changing the volume of measuring tube 106 between ports 3 and 6.

Next, as shown in FIG. 2 the six port valve is turned ⅙th clockwise so that now port 3 is connected by an internal tube to port 5 and port 6 is connected by an internal tube to port 4. After turning valve 102 a ⅙th turn clockwise, there is now a very precise amount of chemical from bulk supply 104 contained in tube 106. This precisely measured amount of chemical is now ready for use in one of several different methods.

In one embodiment of the present invention as shown in FIG. 2, a bulk supply of water 112 which is to be mixed with the chemical liquid from bulk supply 104 is coupled to port 4 of 6-port valve 102. DI water flows through port 4 through the internal conduit to port 6 where it pushes out the precisely measured amount of chemical in measuring tube 106 through port 6 to port 3 as shown in FIG. 2. Coupled to port 5 is a reservoir or chamber 111. DI water pushes the precisely measured amount chemical into reservoir 111. DI water is continually fed into the reservoir 111 until a preset level is reached as indicated by a level sensor 114. In this way, a precise amount of chemical can be mixed with DI water to form a chemical mixture 113.

In an embodiment of the present invention as shown in FIG. 2, the chamber 111 is pressurized with an inert gas, such as N₂, to push the chemical mixture 113 contained in reservoir 111 through a dispenser or spray nozzle 116 onto a wafer 118 which is attached to a spinning or rotating support 120.

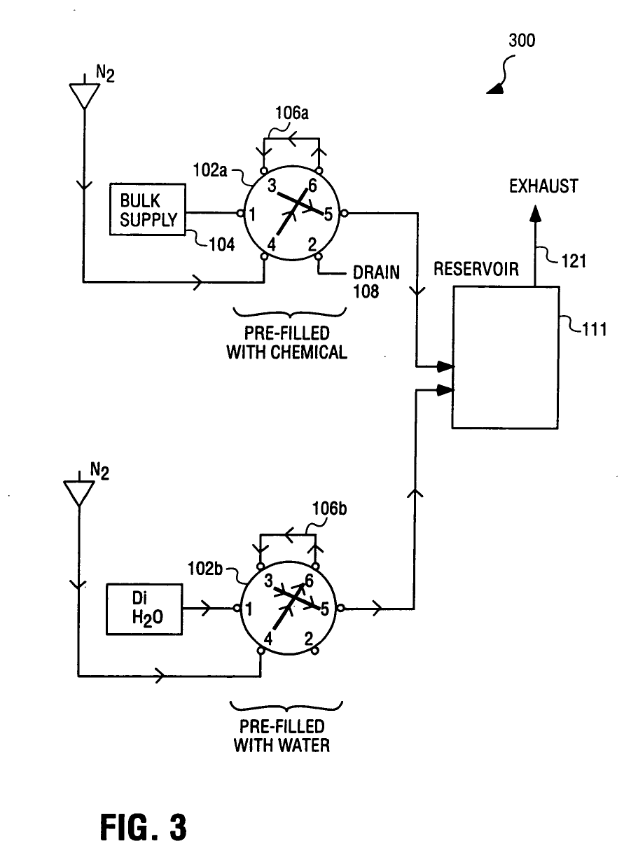

FIG. 3 illustrates a mixing system 300 and method which can be used to precisely mix a chemical with DI water. In system 300 shown in FIG. 3, one 6-port valve 102a is used to provide a precise amount of a chemical to reservoir or chamber 111 and the second 6-port valve 102b is used to provide a precise amount of DI water to reservoir 111. Valve 102a and valve 102b in FIG. 3 have already been charged or pre-filled so that measuring tube 106a contains a precisely measured amount chemical from bulk supply 104 and so that measuring tube 106b contains a precisely measured amount of DI water. In system 300 shown in FIG. 3, both the chemical in measuring tube 106a and the DI water in measuring tube 106b are pushed into reservoir 111 by an inert gas such as N₂ coupled to port 4 of 6-port valves 102a and 102b. An exhaust outlet 121 is provided in reservoir 111. System 300, as shown in FIG. 3, enables the precise mixing of a chemical with DI water without the need for a level sensor. It is advantageous to avoid the use of level sensors since they are prone to failure.

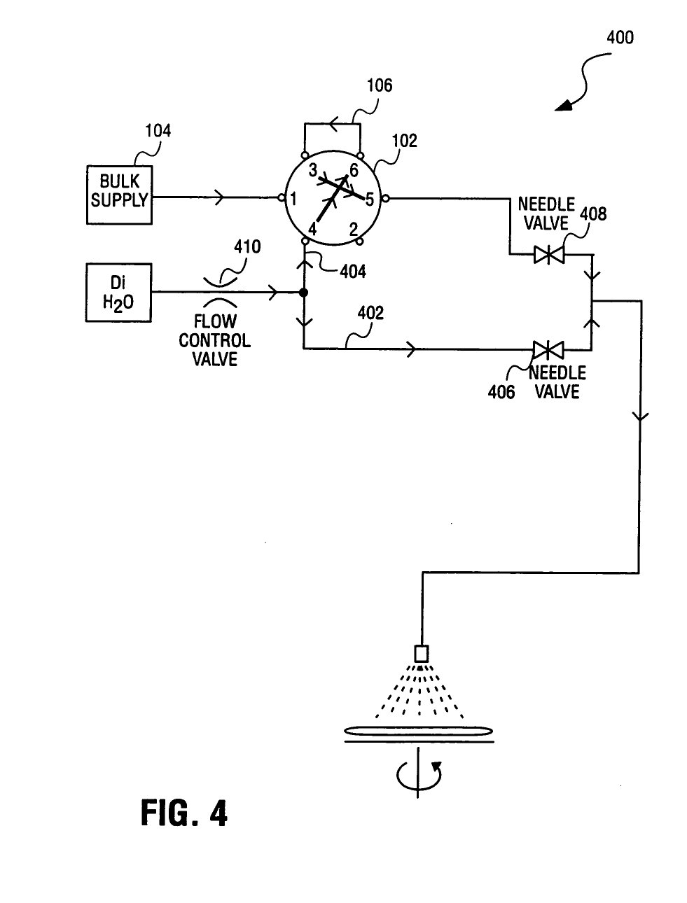

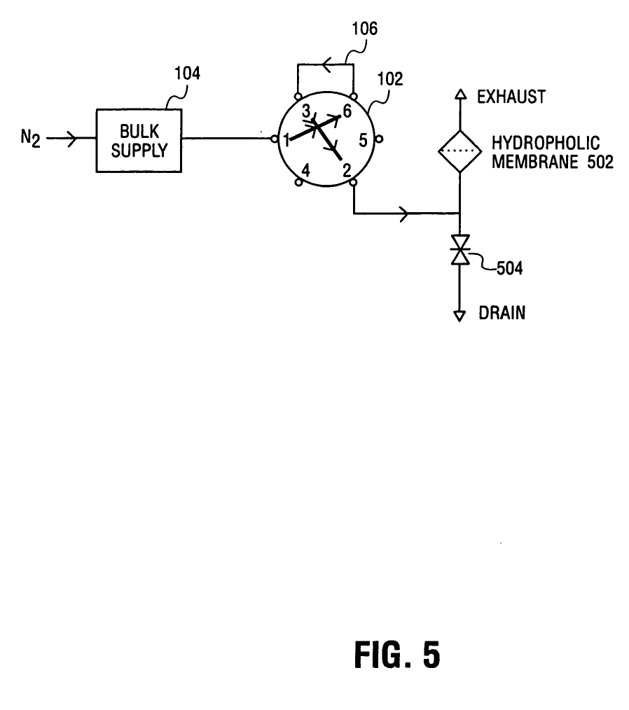

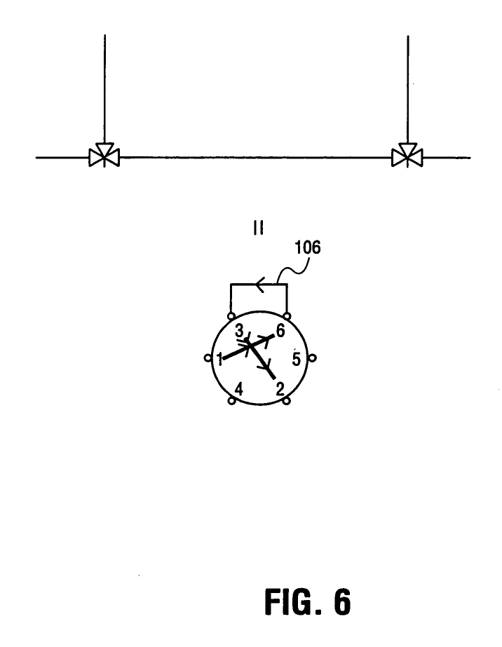

In another system 400 in accordance with an embodiment of the present invention as shown in FIG. 4, no intermediate chamber or reservoir 111 is used. In system 400 DI water splits into two flows, a main flow 402 and flow 404 to port 4 of 6-port valve 102. In FIG. 4 6-port valve 102 is shown in the pre-filled or “charged” position so that measuring tube 106 has a precisely measured amount of chemical from bulk supply 104. The split between the two flows 402 and 404 can be controlled by two needle valves 406 and 408. An advantage of system 400 is that once the chemical is used up, no more etching or cleaning can occur since now only DI water is flowing through both legs. The reaction, therefore, is self limiting. No over exposure can occur. The etch time is determined by the length of measuring tube 106 between ports 3 and 6, and by the flow rate through the 6-port valve. The concentration is determined by the split and flows through the two needle valves. If the flow control valve 410 which controls the total DI water flow is not entirely accurate, the concentration will now deviate in the same amount since the variation occurs equally in both legs and therefore the variations cancel out. In FIG. 5 an improved method and apparatus for filling measuring tube 106 of 6-port valve 102 is illustrated. In FIG. 5 6-port valve 102 is shown in the charging or filling position (e.g. such as FIG. 1). During the filling cycle, a hydrophobic membrane 502 is used to separate the chemicals in bulk supply 104 from the inert gas such as N₂ used to push the bulk chemicals. A drain valve 504 can be used to drain any chemicals out of the membrane after filling.

Thus, a method and apparatus for precisely mixing chemicals in a single wafer process has been described. It is to be appreciated that the present invention is not to be limited to the specific details set forth in the preferred embodiment herein. For example, although the present invention has been described with respect to a preferred embodiment where a chemical is mixed with DI water, the present invention is equally useful for mixing any two chemicals. Additionally, although the present invention ideally uses 6-port valves it is to be appreciated that other valving systems, such as two 3-port valves as shown in FIG. 6, which provide the same functionality as a 6-port valve may be used.

1-16. (canceled)

1. A method of generating a measured amount of a liquid chemical in a single semiconductor wafer etching or cleaning process comprising:
flowing a liquid chemical into a valve system having a tube of a known volume;
filling said tube with said known volume with said liquid chemical, wherein filling said tube generates a measured amount of said liquid chemical approximately equal to the known volume of the tube;
wherein the measured amount of liquid chemical is pushed out of the tube with a flushing fluid, comprising a precisely measured amount of DI water;
mixing precisely the measured amount of the liquid chemical with the precisely measured DI water in a pressurized chamber;
wherein the pressurized chamber has an internal pressure throughout the chamber that is substantially greater than one atmosphere; and
applying approximately the entire chemical mixture within the pressurized chamber to a single wafer in a single wafer process, wherein an inert gas pushes the chemical mixture through a dispenser or spray nozzle onto the wafer;
wherein the applied chemical mixture is of a known measured concentration.

2. The method of claim 1, wherein said valve system comprises a 6-port valve.

3. The method of claim 1, wherein said valve system comprises two 3-port valves.

4. The method of claim 1, further comprising the step of changing the amount of liquid chemical used by changing the volume of said tube.

5. A method of mixing chemicals comprising:
flowing a first liquid chemical into a valve system having a tube of a known volume;
filling said tube with said first liquid chemical, wherein filling said tube generates a measured amount of said first liquid chemical approximately equal to the known volume of the tube;
flowing a second liquid chemical into said valve system to push only said measured amount of said first liquid chemical into a chamber with said second liquid chemical;
continuing to flow said second liquid chemical into said chamber until a predetermined level is reached in said chamber to form a mixed solution of a known measured concentration;
wherein said chamber is pressurized, wherein the internal pressure throughout the chamber is substantially greater than one atmosphere; and
dispensing approximately the entire chemical mixture within the chamber onto a wafer;
wherein an inert gas pushes the chemical mixture out of the chamber.

6. The method of claim 5, wherein the second liquid chemical is DI water.

7. The method of claim 5, further comprising the steps of changing the amount of liquid chemical used by changing the volume of said tube.

8. The method of claim 5, further comprising dispensing said mixed solution onto a single spinning wafer by pressurizing said chamber.

9. The method of claim 5, wherein said valve system comprises a 6-port valve.

10. The method of claim 5, wherein said valve system comprises two 3-port valves.

11. A method of mixing chemicals comprising:
flowing a first liquid chemical into a first valve system having a first tube of a known volume and completely filling said first tube with said first liquid chemical to generate a measured amount of said first liquid chemical;
flowing a second liquid chemical into a second valve system having a second tube of a known volume and completely filling said second tube with said second liquid chemical to generate a measured amount of said second liquid chemical;
wherein, the first and second tubes are external to the valves in the first and second valve systems;
flowing a first and second flushing fluid into said first and second valve systems, respectively, to discharge only said measured amount of said first liquid chemical into a first exhaust unit and only said measured amount of said second liquid chemical into a second exhaust unit, wherein precisely said measured amount of first liquid chemical and precisely said measured amount of second liquid chemical are mixed together, forming a chemical mixture;
wherein, at least one of said first and second flushing fluids have an approximately know volume; and
dispensing the chemical mixture onto a wafer, wherein an inert gas pushes the chemical mixture out onto the wafer with an absolute pressure substantially greater than one atmosphere.

12. The method of claim 11, wherein said first and second exhaust units comprise a single reservoir.

13. The method of claim 11, wherein the first flushing fluids are selected from a group consisting of the said second liquid chemical, the said second flushing fluid, DI water, and an inert gas.

14. The method of claim 13, wherein the second flushing fluids are selected from a group consisting of the said first liquid chemical, the said first flushing fluid, DI water, and an inert gas.

15. The method of claim 1 1, wherein said first and said second valve systems each comprise a 6-port valve.

16. The method of claim 11, wherein said first and second valve systems each comprise two 3-port valves.

17. The method of claim 11 wherein said first and second valve systems comprise a combination of a 6-port valve and two 3-port valves.
